(19) United States
(12) Patent Application Publication
(10) Pub. No.: US 2026/0186422 A1
(43) Pub. Date: Jul. 2, 2026

(54) RESIST PATTERN INSPECTION METHOD, RESIST PATTERN MANUFACTURING METHOD, SUBSTRATE SELECTION METHOD, AND MANUFACTURING METHOD FOR SEMICONDUCTOR PACKAGE SUBSTRATE OR PRINTED CIRCUIT BOARD

(71) Applicant: Resonac Corporation, Tokyo (JP)

(72) Inventor: Tetsuya KATO, Tokyo (JP)

(21) Appl. No.: 18/858,192

(22) PCT Filed: Jul. 10, 2023
(86) PCT No.: PCT/JP2023/025480

§ 371 Date: Oct. 18, 2024

(30) Foreign Application Priority Data
Jul. 27, 2022 (JP) 2022-119526

(51) Int. Cl. G03F 7/00; G01N 21/64; G01N 21/95; G01N 21/956; H10W 70/05

(52) U.S. Cl. CPC G03F 7/70625; G01N 21/643; G01N 21/9501; G01N 21/956; G03F 7/7065; G03F 7/706837; H10W 70/05

(57) ABSTRACT

A resist pattern inspection method includes performing an outer appearance inspection on a resist pattern based on light emission from a substrate on which the resist pattern is formed. A resist pattern manufacturing method includes forming a resist pattern on a substrate; and adhering a light-emitting material on a conductor surface of the substrate. A substrate selection method includes performing an outer appearance inspection on a resist pattern based on light emission from a substrate on which the resist pattern is formed; and evaluating the resist pattern based on the outer appearance inspection in performing the outer appearance inspection. A manufacturing method for a semiconductor package substrate or a printed circuit board includes forming a conductor pattern by performing etching process or plating process on the substrate in which evaluation of the resist pattern in the substrate selection method satisfies a reference.

### TECHNICAL FIELD

The present disclosure relates to a resist pattern inspection method, a resist pattern manufacturing method, a substrate selection method, and a manufacturing method for a semiconductor package substrate or a printed circuit board.

### BACKGROUND ART

In the case of manufacturing a semiconductor package substrate or a printed circuit board, first, a photosensitive layer is laminated on the substrate. Next, a predetermined portion of the photosensitive layer is irradiated with an active ray through a photomask to cure an exposed portion. Next, after a support is peeled off and removed, an unexposed portion of the photosensitive layer is removed with a developer to form a resist pattern on the substrate. Next, using the formed resist pattern as a mask, the substrate on which the resist pattern is formed is subjected to an etching process or a plating process to form a conductor pattern on the substrate, and finally, a cured portion (resist pattern) of the photosensitive layer is peeled off and removed from the substrate.

In such a manufacturing step of a semiconductor package substrate or a printed circuit board, when an exposure failure of an active ray occurs due to a foreign substance or the like adhered to a photomask or a photosensitive layer, a defect occurs in a resist pattern, and a defect such as disconnection or short circuit may occur in a conductor pattern. Therefore, conventionally, failures such as disconnection or short circuit of the conductor pattern have been inspected by performing the outer appearance inspection on the conductor pattern.

### CITATION LIST

### Patent Literature

Patent Literature 1: Japanese Unexamined Patent Publication No. 2005-207802

### SUMMARY OF INVENTION

### Technical Problem

A failure can be found at an earlier stage in the manufacturing of the semiconductor package substrate or the printed circuit board by performing the outer appearance inspection on the resist pattern before forming the conductor pattern. In addition, the resist pattern formation can be improved by evaluating the yield of the resist pattern formation. Outer appearance inspection of a resist pattern has been conventionally performed using a scanning electron microscope (hereinafter also referred to as “SEM”) (see e.g., Patent Literature 1).

However, the inspection by the SEM inspects a minimum range of about 1 mm². For this reason, the inspection of the resist pattern of the entire semiconductor package substrate or printed circuit board using the SEM requires an enormous time. Furthermore, the inspection accuracy varies greatly depending on the inspector and the SEM used for the inspection.

Therefore, an object of the present disclosure is to provide a resist pattern inspection method, a resist pattern manufacturing method, a substrate selection method, and a manufacturing method for a semiconductor package substrate or a printed circuit board capable of evaluating a resist pattern with high accuracy in a short time.

### Solution to Problem

[1] A resist pattern inspection method of the present disclosure includes performing an outer appearance inspection of a resist pattern based on light emission from a substrate on which the resist pattern is formed.

In this resist pattern inspection method, since the resist pattern is subjected to the outer appearance inspection based on light emission from the substrate on which the resist pattern is formed, defects of the resist pattern can be detected with high accuracy in a short time as compared with an outer appearance inspection using an SEM.

[2] In the resist pattern inspection method according to [1], performing the outer appearance inspection may include detecting a contour of the resist pattern based on light emission from the substrate, and performing the outer appearance inspection of the resist pattern based on the detected contour. In this resist pattern inspection method, the outer appearance inspection of the resist pattern can include appropriately performing the outer appearance inspection on the resist pattern by using the contour of the resist pattern detected based on light emission from the substrate.

[3] In the resist pattern inspection method according to [2], performing the outer appearance inspection may include comparing the detected contour with pattern data for forming the resist pattern. In the resist pattern inspection method, the defect of the resist pattern can be detected with high accuracy by comparing the detected contour with the pattern data for forming the resist pattern as the outer appearance inspection of the resist pattern.

[4] In the resist pattern inspection method according to [2], performing the outer appearance inspection may include measuring a line width of the resist pattern based on the detected contour. In this resist pattern inspection method, the formation state of the resist pattern can be evaluated by measuring the line width of the resist pattern based on the detected contour as the outer appearance inspection of the resist pattern.

[5] The resist pattern inspection method according to any one of [1] to [4] may further include forming the resist pattern on the substrate and adhering a light-emitting material on a conductor surface of the substrate. In this resist pattern inspection method, since the light emission intensity from the conductor surface of the substrate increases by adhering the light-emitting material onto the conductor surface of the substrate, the contrast between the light emission from the region where the resist pattern is not formed in the conductor surface of the substrate and the light emission from the region where the resist pattern is formed in the conductor surface of the substrate increases. Therefore, the detection accuracy of the contour of the resist pattern based on the light emission from the substrate can be enhanced.

[6] In the resist pattern inspection method according to [5], the forming of the resist pattern may include forming the resist pattern having a thickness of greater than or equal to 0.05 μm and less than or equal to 500 μm. In this resist pattern inspection method, by forming the resist pattern having a thickness of greater than or equal to 0.05 μm and less than or equal to 500 μm, the contrast between the light emission from the region where the resist pattern is not formed in the conductor surface of the substrate and the light emission from the region where the resist pattern is formed in the conductor surface of the substrate can be increased while suppressing the resist pattern from becoming too thick. Therefore, the detection accuracy of the contour of the resist pattern based on the light emission from the substrate can be enhanced.

[7] A resist pattern manufacturing method according to the present disclosure includes forming a resist pattern on a substrate; and adhering a light-emitting material on a conductor surface of the substrate.

In this resist pattern manufacturing method, since the light emission intensity from the conductor surface of the substrate increases by adhering the light-emitting material onto the conductor surface of the substrate, the contrast between the light emission from the region where the resist pattern is not formed in the conductor surface of the substrate and the light emission from the region where the resist pattern is formed in the conductor surface of the substrate increases. Therefore, for example, in a case where the contour of the resist pattern is detected based on light emission from the substrate on which the resist pattern is formed, the detection accuracy can be enhanced. In addition, in a case where the line width of the resist pattern is measured or the like, it is easy to focus on the surface of the resist pattern or the contour of the resist pattern.

[8] In the resist pattern manufacturing method according to [7], wherein the forming of the resist pattern may include forming the resist pattern having a thickness of greater than or equal to 0.05 μm and less than or equal to 500 μm. In this resist pattern manufacturing method, by forming the resist pattern having a thickness of greater than or equal to 0.05 μm and less than or equal to 500 μm, the contrast between the light emission from the region where the resist pattern is not formed in the conductor surface of the substrate and the light emission from the region where the resist pattern is formed in the conductor surface of the substrate can be increased while suppressing the resist pattern from becoming too thick. Therefore, for example, the detection accuracy of the contour of the resist pattern based on the light emission from the substrate can be enhanced.

[9] A substrate selection method according to the present disclosure includes performing an outer appearance inspection on a resist pattern based on light emission from a substrate on which the resist pattern is formed; and evaluating the resist pattern based on the outer appearance inspection in performing the outer appearance inspection.

In the substrate selection method, since the resist pattern is evaluated by the outer appearance inspection of the resist pattern based on the light emission from the substrate, the substrate can be selected with high accuracy in a short time as compared with the outer appearance inspection using the SEM.

[10] The substrate selection method according to [9], wherein evaluating may include evaluating the resist pattern according to the number of shape of defects of the resist pattern. In this substrate selection method, the substrate can be appropriately evaluated by evaluating the resist pattern according to the number or shape of defects of the resist pattern.

[11] In the substrate selection method according to [9] or [10], a light-emitting material may be adhered on a conductor surface of the substrate to be subjected to outer appearance inspection in performing the outer appearance inspection. In this substrate selection method, since the light-emitting material is adhered on the conductor surface of the substrate to be subjected to the outer appearance inspection in performing the outer appearance inspection, the contrast between the light emission from the region where the resist pattern is not formed in the conductor surface of the substrate and the light emission from the region where the resist pattern is formed in the conductor surface of the substrate increases. Therefore, the outer appearance inspection of the resist pattern can be performed with high accuracy.

[12] A manufacturing method for a semiconductor package substrate or a printed circuit board according to the present disclosure including forming a conductor pattern by performing etching process or plating process on a substrate in which the evaluation of the resist pattern in the substrate selection method according to any one of [9] to [11] satisfies a reference.

In the manufacturing method for a semiconductor package substrate or a printed circuit board, the conductor pattern is formed by performing etching process or plating process on the substrate in which the evaluation of the resist pattern in the substrate selection method described above satisfies the references, so that the occurrence of failures such as disconnection or short circuit of the conductor pattern can be suppressed.

### Advantageous Effects of Invention

According to the present disclosure, a resist pattern can be evaluated with high accuracy in a short time.

### BRIEF DESCRIPTION OF DRAWINGS

FIG. 1A is a schematic perspective view for explaining a photosensitive layer forming step in a resist pattern forming step, FIG. 1B is a schematic perspective view for explaining an exposure step in the resist pattern forming step, and FIG. 1C is a schematic perspective view for explaining a developing step in the resist pattern forming step.

FIGS. 2A, 2B, and 2C are schematic perspective views for explaining formation of a conductor pattern based on a defective resist pattern.

FIG. 3 is a schematic perspective view for explaining an outer appearance inspection step.

FIG. 4 is a schematic view for explaining light emission from a substrate.

FIG. 5 is a schematic view for explaining pattern data.

FIGS. 6A, 6B, and 6C are schematic perspective views for explaining formation of a conductor pattern.

### DESCRIPTION OF EMBODIMENTS

Hereinafter, embodiments of a resist pattern inspection method, a resist pattern manufacturing method, a substrate selection method, and a manufacturing method for a semiconductor package substrate or a printed circuit board of the present disclosure will be described with reference to the drawings. In all the drawings, the same or corresponding parts are denoted by the same reference numerals. In addition, “A or B” only needs to include either A or B, and may include both A and B.

### [Resist Pattern Inspection Method]

A resist pattern inspection method according to an embodiment includes an outer appearance inspection step of performing outer appearance inspection of a resist pattern based on light emission from a substrate on which the resist pattern is formed. The resist pattern inspection method may include a resist pattern forming step of forming a resist pattern on the substrate before the outer appearance inspection step. In addition, the resist pattern inspection method may include a light-emitting material adhesion step of adhering a light-emitting material on the conductor surface of the substrate. The resist pattern inspection method may include other steps. In the present specification, the term “step” includes not only an independent step but also a step that cannot be clearly distinguished from other steps as long as an intended action of the step is achieved. The resist pattern can be said to be a photocured product pattern of a photosensitive resin composition or can also be said to be a relief pattern.

### <Resist Pattern Forming Step>

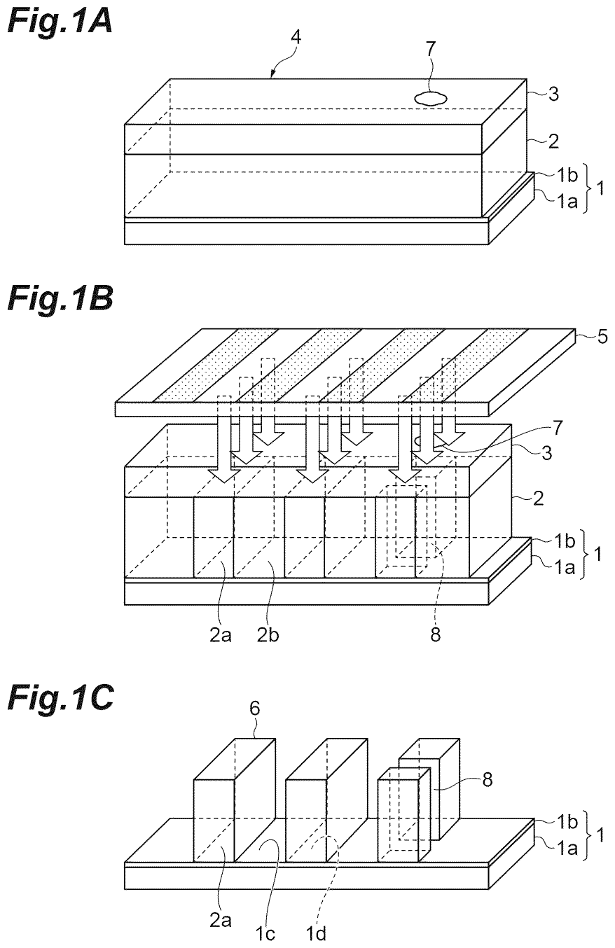

As illustrated in FIG. 1, the resist pattern forming step includes a photosensitive layer forming step of stacking a photosensitive layer on a substrate (see FIG. 1A), an exposure step of irradiating a predetermined portion of the photosensitive layer with an active ray to form a photocured portion (see FIG. 1B), and a developing step of removing a region other than the predetermined portion of the photosensitive layer from the substrate (see FIG. 1C). The resist pattern forming method may include other steps as necessary.

### (Photosensitive Layer Forming Step)

As illustrated in FIG. 1A, in the photosensitive layer forming step, a photosensitive layer 2 and a support 3 are formed on the substrate 1. The substrate 1 includes, for example, an insulating layer 1a and a conductor layer 1b formed on the insulating layer 1a. The photosensitive layer 2 is formed on the conductor layer 1b of the substrate 1. The conductor layer 1b is, for example, electroless copper plating.

The photosensitive layer 2 is a layer formed using a photosensitive resin composition whose properties change (e.g., photocuring is performed) when irradiated with light. The photosensitive resin composition for forming the photosensitive layer 2 contains, for example, a binder polymer, a photopolymerizable compound, and a photopolymerization initiator. The photosensitive resin composition for forming the photosensitive layer 2 may contain a photosensitizer, a polymerization inhibitor, or other components as necessary. The photosensitive resin composition for forming the photosensitive layer 2 may contain additives such as, for example, dyes such as malachite green, Victoria Pure Blue, Brilliant Green and methyl violet, photochromic agents such as tribromophenylsulfone, leucocrystal violet, diphenylamine, benzylamine, triphenylamine, diethylaniline and o-chloroaniline, heat generation inhibitors, plasticizers such as p-toluenesulfonamide, pigments, fillers, defoamers, flame retardants, adhesion imparting agents, leveling agents, peeling accelerators, antioxidants, fragrances, imaging agents and thermal crosslinking agents.

As the support 3, for example, a polymer film (supporting film) having heat resistance and solvent resistance, such as for example, polyester such as polyethylene terephthalate (PET), or polyolefin such as polypropylene or polyethylene, may be used.

As a method of forming the photosensitive layer 2 and the support 3 on the substrate 1, for example, there is a method of using a photosensitive element (not illustrated). The photosensitive element includes, for example, a support, a photosensitive layer, and a protective layer in this order. Then, after the protective layer is removed, the photosensitive layer 2 and the support 3 are formed on the substrate 1 by pressure-bonding the photosensitive layer of the photosensitive element to the substrate 1 while heating. As a result, a stacked body 4 including the substrate 1, the photosensitive layer 2, the support 3, and the supporting film (not illustrated) in this order is obtained. An intermediate layer or the like may be disposed between the support 3 and the photosensitive layer 2.

### (Exposure Step)

As illustrated in FIG. 1B, in the exposure step, the photosensitive layer 2 is exposed with an active ray through the support 3. As a result, the exposed portion irradiated with the active ray is photocured to form a photocured portion 2a (latent image). As the exposure method, a known exposure method can be applied, and examples thereof include, for example, a method of irradiating an image with an active ray through a photomask 5 called an artwork (mask exposure method), a laser direct imaging (LDI) exposure method, a method of irradiating an image through a lens using an active ray in which an image of a photomask is projected (projection exposure method), or the like.

### (Developing Step)

As illustrated in FIG. 1C, in the developing step, the uncured portion 2b of the photosensitive layer 2 is removed from the substrate 1. A resist pattern 6 including the photocured portion 2a in which the photosensitive layer 2 is photocured is formed on the substrate 1 by the developing step. In addition, a region 1c where the resist pattern 6 is not formed and a region 1d where the resist pattern 6 of the conductor surface of the substrate 1 is formed are formed on the surface of the conductor layer 1b of the substrate 1. The region 1c is also a region of the surface of the conductor layer 1b that is not covered with the resist pattern 6. The region 1d is also a region of the surface of the conductor layer 1b that is covered with the resist pattern 6.

The thickness of the resist pattern 6 formed on the substrate 1 may be, for example, greater than or equal to 0.05 μm, greater than or equal to 0.1 μm, greater than or equal to 1 μm, or greater than or equal to 5 μm. The thickness of the resist pattern 6 formed on the substrate 1 may be, for example, less than or equal to 500 μm, less than or equal to 300 μm, less than or equal to 100 μm, or less than or equal to 60 μm. The minimum value and the maximum value of the thickness of the resist pattern 6 can be appropriately combined. For example, the thickness of the resist pattern 6 formed on the substrate 1 may be greater than or equal to 0.05 μm and less than or equal to 500 μm, greater than or equal to 0.1 μm and less than or equal to 300 μm, greater than or equal to 1 μm and less than or equal to 100 μm, or greater than or equal to 5 μm and less than or equal to 60 μm. The thickness of the resist pattern 6 is a height with respect to the substrate 1 in a direction perpendicular to the main surface of the substrate 1.

The resist pattern 6 formed on the substrate 1 has, for example, light-emitting property. The light emission is also called luminescence (cold light) or the like, and for example, refers to emitting light by absorbing excitation light or the like when irradiated with excitation light such as inspection light. In addition, light emission refers to light emitted in this manner. Examples of the light emission include fluorescence and phosphorescence. Fluorescence is light emission in which light emission immediately stops when irradiation with excitation light is stopped. Phosphorescence is light emission in which light emission continues even when irradiation of light such as inspection light is stopped. Having light-emitting property means having the property of emitting light, that is, having a property of emitting light by absorbing excitation light or the like when irradiated with excitation light. Note that the resist pattern 6 may not have light-emitting property.

### <Light-Emitting Material Adhesion Step>

In the light-emitting material adhesion step, a light-emitting material is adhered onto the conductor surface of the substrate 1 in order to increase the light emission intensity of the substrate 1. The conductor surface of the substrate 1 is, for example, a surface of the conductor layer 1b on the side opposite to the insulating layer 1a, and is a surface of the conductor layer 1b on the side on which the resist pattern 6 is formed. Therefore, in the light-emitting material adhesion step, the light-emitting material is adhered onto the surface of the conductor layer 1b of the substrate 1. The light-emitting material is a material that emits light when irradiated with excitation light. When the light-emitting material is a fluorescent material, this light emission becomes fluorescent. When the light-emitting material is a phosphorescent material, this light emission becomes phosphorescent. As the light-emitting material (fluorescent material or phosphorescent material), for example, a light-emitting dye (fluorescent dye or phosphorescent dye) that emits light when irradiated with excitation light may be used. As the light-emitting dye, for example, a xanthene dye, a coumarin dye, a pyrazoline dye, a dipyrromethene dipromethene dye, an anthracene dye, a pyrene dye, a perylene dye, a lophine dye (also referred to as a lophine, a lophine compound, etc.) and the like may be used. As the light-emitting material, for example, a fluorescent stain containing a light-emitting dye may be used. The light-emitting material adhesion step can be performed, for example, at any timing before the resist pattern forming step, in the middle of the resist pattern forming step, or after the resist pattern forming step.

In the light-emitting material adhesion step, for example, the substrate 1 can be immersed in a fluorescent stain serving as a light-emitting material. Examples of the fluorescent stain include, for example, saturated solutions of a xanthene dye, a coumarin dye, a pyrazoline dye, a dipyrromethene dipromethene dye, an anthracene dye, a pyrene dye, a perylene dye, and a lophine dye, and mixed solutions thereof. The dye may contain, for example, imidazole, pyridine, oxazole, pyrazole, thiazole, triazine, triazole, benzotriazole, 5-carboxybenzotriazole, tetrazole, 5-aminotetrazole, thiol, thiophene, or benzoxazolylthiophene as a substituent. These substituents may be used singly or in combination of two or more kinds thereof. For example, a saturated aqueous solution of rhodamine B (FUJIFILM Wako Pure Chemical Corporation) which is a xanthene dye is used. Examples of the solvent include water, methanol, ethanol, acetone, methyl ethyl ketone, methyl cellosolve, ethyl cellosolve, toluene, N, N-dimethylformamide, propylene glycol monomethyl ether, and mixed solvents thereof. In this case, the entire substrate 1 may be immersed in the fluorescent stain, or a part of the substrate 1 may be immersed in the fluorescent stain such that the entire substrate 1 is immersed in the fluorescent stain. For example, a fluorescent stain may be dropped on the substrate 1 on which the resist pattern 6 is formed. In this case, the fluorescent stain may be dropped on the entire substrate 1, or the fluorescent stain may be dropped on a part of the substrate 1 on which the resist pattern 6 is formed such that the fluorescent stain is dropped on the entire substrate 1. Furthermore, for example, in the developing step in the resist pattern forming step, a light-emitting material may be added to a developer and a rinse solution for removing the uncured portion 2b of the photosensitive layer 2 from the substrate 1. After the fluorescent dye is adhered onto the conductor surface of the substrate 1, the fluorescent dye liquid is removed from a region other than the conductor surface of the substrate 1. As a method for removing the fluorescent stain, for example, after the fluorescent dye is adhered onto the conductor surface of the substrate 1, the substrate 1 may be sufficiently washed with water and air-blown and dried.

Before the substrate 1 is immersed in a fluorescent stain serving as a light-emitting material, the conductor surface of the substrate 1 may be treated with a rust preventive agent. That is, before the light-emitting material adhesion step, a rust preventive agent adhesion step of adhering a rust preventive agent to the conductor surface of the substrate 1 may be performed. Examples of the rust preventive agent include, for example, imidazole, imidazole derivatives, pyridine, pyridine derivatives, oxazole, oxazole derivatives, pyrazole, pyrazole derivatives, thiazole, thiazole derivatives, triazine, triazine derivatives, triazole, triazole derivatives, benzotriazole, benzotriazole derivatives, 5-carboxybenzotriazole, 5-carboxybenzotriazole derivatives, tetrazole, tetrazole derivatives, 5-aminotetrazole, 5-aminotetrazole derivatives, thiol, thiol derivatives, thiophene, thiophene derivatives, benzoxazolylthiophene, and benzoxazolylthiophene derivatives. The rust preventive agent may be diluted with a solvent. These rust preventive agents may be used singly or in combination of two or more kinds thereof. Examples of the solvent include water, methanol, ethanol, acetone, methyl ethyl ketone, methyl cellosolve, ethyl cellosolve, toluene, N, N-dimethylformamide, propylene glycol monomethyl ether, and mixed solvents thereof. In this case, the entire substrate 1 may be immersed in the rust preventive agent, or a part of the substrate 1 may be immersed in the rust preventive agent such that the entire substrate 1 is immersed in the rust preventive agent. Furthermore, for example, a rust preventive agent may be dropped on the substrate 1 on which the resist pattern 6 is formed. In this case, the rust preventive agent may be dropped on the entire substrate 1, or the rust preventive agent may be dropped on a part of the substrate 1 on which the resist pattern 6 is formed so that the rust preventive agent is dropped on the entire substrate 1. Furthermore, for example, in the developing step in the resist pattern forming step, a rust preventive agent may be added to a developer and a rinse solution for removing the uncured portion 2b of the photosensitive layer 2 from the substrate 1. After the rust preventive agent is adhered onto the conductor surface of the substrate 1, the rust preventive agent is removed from a region other than the substrate 1. As a method for removing the rust preventive agent, for example, after the rust preventive agent is adhered onto the conductor surface of the substrate 1, the substrate may be sufficiently washed and air blow dried.

The light-emitting material and the rust preventive agent may be mixed, and the treatment of the conductor surface of the substrate 1 with the rust preventive agent and the treatment of the conductor surface of the substrate 1 with the light-emitting material may be performed simultaneously. That is, the light-emitting material adhesion step and the rust preventive agent adhesion step may be performed together. Only one of the treatment of the conductor surface of the substrate 1 with the rust preventive agent and the treatment of the conductor surface of the substrate 1 with the light-emitting material may be performed.

### <Outer Appearance Inspection Step>

In the outer appearance inspection step, the outer appearance of the resist pattern 6 is inspected based on light emission (fluorescence or phosphorescence) from the substrate 1 on which the resist pattern 6 is formed. That is, in the outer appearance inspection step, the outer appearance of the resist pattern 6 is inspected based on the light emitted from the substrate 1.

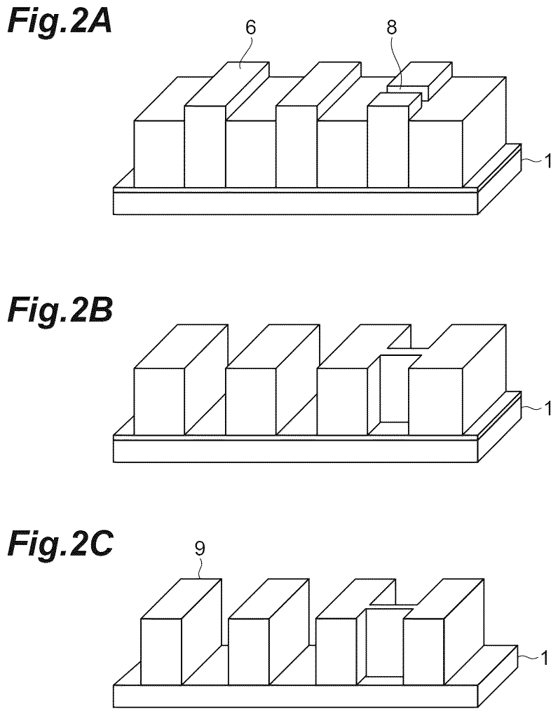

By the way, in the exposure step described above, when an exposure failure of an active ray occurs due to a foreign substance 7 (see FIG. 1) or the like adhered to the photomask 5, the support 3, or the photosensitive layer 2, a defect 8 may occur in the resist pattern 6. More specifically, as illustrated in FIGS. 2A, 2B, and 2C, in the manufacturing of the semiconductor package substrate or the printed circuit board, a conductor pattern 9 is formed by performing etching process or plating process on the substrate 1 on which the resist pattern 6 is formed. Therefore, when there is the defect 8 in the resist pattern 6, a failure such as disconnection or short circuit may occur in the conductor pattern 9 formed by the etching process or the plating process. In the exposure step, the line width of the resist pattern 6 may be increased or decreased depending on the exposure state of the active ray.

Therefore, in the outer appearance inspection step, the resist pattern 6 is subjected to the outer appearance inspection in order to find a failure before forming the conductor pattern. In the outer appearance inspection step, for example, a contour of the resist pattern 6 is detected based on light emission from the substrate 1, and the outer appearance of the resist pattern 6 is inspected based on the detected contour.

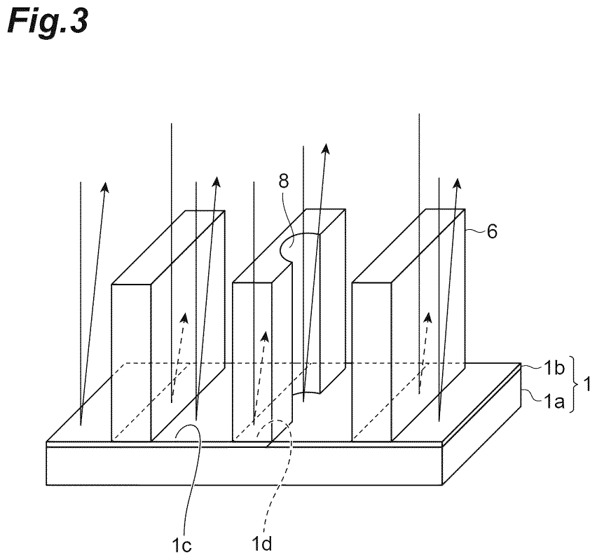

As illustrated in FIG. 3, first, inspection light serving as excitation light is emitted to the substrate 1 on which the resist pattern 6 is formed, and light emitted from the substrate 1 is received. That is, the light emitted by the substrate 1 is received. The wavelength of the inspection light may be, for example, less than or equal to 390 nm, less than or equal to 380 nm or less than or equal to 370 nm. Furthermore, the wavelength of the inspection light may be, for example, greater than or equal to 190 nm, greater than or equal to 250 nm, or greater than or equal to 300 nm. The minimum value and the maximum value of these wavelengths can be appropriately combined. For example, the wavelength of the inspection light may be less than or equal to 390 nm and greater than or equal to 190 nm, less than or equal to 380 nm and greater than or equal to 250 nm, or less than or equal to 370 nm and greater than or equal to 300 nm. Note that as a light source of the inspection light, a gas laser such as a carbon arc lamp, a mercury vapor arc lamp, a high pressure mercury lamp, an ultra-high pressure mercury lamp, a xenon lamp, or an argon laser, a solid laser such as a YAG laser, a semiconductor laser, a light source such as an LED, or the like may be used, and only light having a wavelength of the inspection light can be used due to an optical filter. The region of the wavelength at which the emitted light is sensed can be arbitrarily changed, and for example, may be a visible light of 400 nm to 800 nm. The wavelength region of the light emission sensing may be blue light of 400 nm to 500 nm, green light of 500 nm to 600 nm, or red light of 600 nm to 800 nm, and the wavelength can be used in one region alone or in combination of two or more regions. The light receiving region of the substrate 1 that receives light emission in the outer appearance inspection step may be, for example, greater than or equal to 1 cm² and less than or equal to 2500 cm², greater than or equal to 5 cm² and less than or equal to 1200 cm², or greater than or equal to 25 cm² and less than or equal to 600 cm².

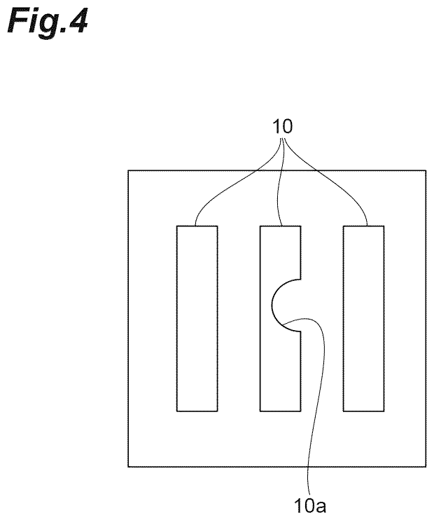

Next, as illustrated in FIGS. 3 and 4, a contour 10 of the resist pattern 6 is specified based on the contrast between the light emission from the region 1c of the conductor surface of the substrate 1 where the resist pattern 6 is not formed and the light emission from the region 1d of the conductor surface of the substrate 1 where the resist pattern 6 is formed. For example, in a light receiving image of light emission, a boundary at which contrast such as brightness or chromaticity increases is detected. Then, the detected boundary is specified as the contour 10 of the resist pattern 6. For the detection of the contour 10 of the resist pattern 6 based on the light emission from the substrate 1, for example, an optical automatic outer appearance inspection device such as AOI Orbotech Ultra Dimension 800 (Manufactured by Japan Orbotech Co., Ltd., Trade name) is used.

Examples of the outer appearance inspection of the resist pattern 6 include an inspection for checking the presence or absence of the defect 8 of the resist pattern 6, an inspection for checking the shape, position, size, and the like (hereinafter also referred to as “shape and the like”) of the defect 8 of the resist pattern 6, an inspection for checking the shape of the resist pattern 6, or an inspection for measuring the line width of the resist pattern 6.

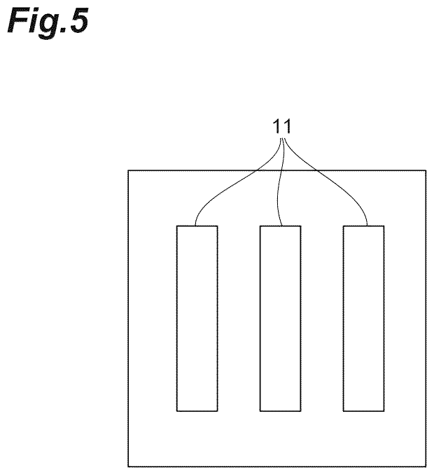

In the inspection for checking the presence or absence of the defect 8 of the resist pattern 6, for example, as illustrated in FIGS. 4 and 5, the contour 10 of the resist pattern 6 detected based on light emission from the substrate 1 is compared with pattern data 11 for forming the resist pattern 6 in the resist pattern forming step. As the pattern data 11, for example, CAD data of the resist pattern 6 is used. Then, with respect to the pattern data 11, a place 10a where the detected contour 10 is different is detected as the defect 8 of the resist pattern 6. Then, the number of detected defects 8 is calculated.

In the inspection for checking the shape and the like of the defect 8 of the resist pattern 6, for example, as illustrated in FIGS. 4 and 5, the contour 10 of the resist pattern 6 detected based on light emission from the substrate 1 is compared with pattern data 11 for forming the resist pattern 6 in the resist pattern forming step. Then, with respect to the pattern data 11, a place 10a where the detected contour 10 is different is detected as the defect 8 of the resist pattern 6. Then, the shape and the like of the detected defect 8 are checked based on the contour of the detected defect 8.

In the inspection for checking the shape of the resist pattern 6, for example, as illustrated in FIGS. 4 and 5, the contour 10 of the resist pattern 6 detected based on light emission from the substrate 1 is compared with pattern data 11 for forming the resist pattern 6 in the resist pattern forming step. Then, the degree of difference in the shape of the resist pattern 6 with respect to the pattern data 11 is checked.

In the inspection for measuring the line width of the resist pattern 6, for example, the line width of the resist pattern 6 is measured by measuring the interval between the contours 10 of the resist pattern 6 detected based on light emission from the substrate 1.

### [Resist Pattern Manufacturing Method]

A resist pattern manufacturing method according to an embodiment includes a resist pattern forming step of forming a resist pattern 6 on a substrate 1, and a light-emitting material adhesion step of adhering a light-emitting material onto a conductor surface of the substrate 1. The resist pattern forming step of the resist pattern manufacturing method may be, for example, the same as the resist pattern forming step of the resist pattern inspection method described above. In addition, the light-emitting material adhesion step of the resist pattern manufacturing method may be, for example, similar to the light-emitting material adhesion step of the resist pattern inspection method described above. The resist pattern manufacturing method may include other steps.

### [Substrate Selection Method]

The substrate selection method according to the present embodiment includes an outer appearance inspection step of performing the outer appearance inspection on the resist pattern 6 based on light emission from the substrate 1 on which the resist pattern 6 is formed, and an evaluation step of evaluating the resist pattern 6 based on the outer appearance inspection in the outer appearance inspection step. The outer appearance inspection step of the substrate selection method may be, for example, similar to the outer appearance inspection step of the resist pattern inspection method described above. For example, a light-emitting material may be adhered on the conductor surface of the substrate to be subjected to the outer appearance inspection in the outer appearance inspection step of the substrate selection method. The substrate selection method may include other steps.

### <Evaluation Step>

In the evaluation step, the resist pattern 6 is evaluated based on a predetermined reference.

For example, in the outer appearance inspection step, when the outer appearance inspection of checking the presence or absence of the defect 8 of the resist pattern 6 is performed, in the evaluation step the resist pattern 6 is evaluated based on the number of defects 8 of the resist pattern 6. For example, in the evaluation step, evaluation is made as good if the number of defects 8 in the resist pattern 6 falls below a predetermined number of references, and evaluation is made as failure if the number of defects 8 in the resist pattern 6 exceeds a predetermined number of references.

In addition, for example, in the outer appearance inspection step, in a case where the inspection for checking the shape and the like of the defect 8 of the resist pattern 6 is performed, the resist pattern 6 is evaluated based on the size of the defect 8 of the resist pattern 6 in the evaluation step. For example, in the evaluation step, evaluation is made as good if the shape and the like of the defect 8 of the resist pattern 6 is within a predetermined allowable range, and evaluation is made as failure if the shape of the defect 8 of the resist pattern 6 is outside the predetermined allowable range.

In addition, for example, in the outer appearance inspection step, in a case where the inspection of checking the shape of the resist pattern 6 is performed, the resist pattern 6 is evaluated based on the shape of the resist pattern 6 in the evaluation step. For example, in the evaluation step, evaluation is made as good if the degree of difference in the shape of the resist pattern 6 with respect to the pattern data 11 is within a predetermined allowable range, and evaluation is made as failure if the degree of difference in the shape of the resist pattern 6 with respect to the pattern data 11 is outside the predetermined allowable range.

In addition, for example, in a case where the outer appearance inspection for measuring the line width of the resist pattern 6 is performed in the outer appearance inspection step, the resist pattern 6 is evaluated based on the line width of the resist pattern 6 in the evaluation step. For example, in the evaluation step, evaluation is made as good if the line width of the resist pattern 6 is within a predetermined reference range, and evaluation is made as failure if the line width of the resist pattern 6 is outside the predetermined reference range.

### [Manufacturing Method for Semiconductor Package Substrate or Printed Circuit Board]

A manufacturing method for a semiconductor package substrate or a printed circuit board according to the present embodiment includes a conductor pattern forming step of forming a conductor pattern by performing etching process or plating process on a substrate in which evaluation of a resist pattern in the substrate selection method described above satisfies a reference. That is, in the conductor pattern forming step, the conductor pattern is not formed by performing etching process or plating process on the substrate in which the evaluation of the resist pattern in the substrate selection method does not satisfy the reference. The manufacturing method for the semiconductor package substrate or the printed circuit board according to the present embodiment may include other steps such as a resist pattern removing step as necessary. The manufacturing method for a semiconductor package substrate or a printed circuit board is a method for manufacturing a semiconductor package substrate or a printed circuit board, and is a manufacturing method for a semiconductor package substrate or a manufacturing method for a printed circuit board. A semiconductor package substrate or a printed circuit board is manufactured by the manufacturing method.

In the etching process, the conductor layer of the substrate not covered with the resist is removed by etching using the resist pattern formed on the substrate including the conductor layer as a mask. After the etching process, the resist is removed by removing the resist pattern 6 to form a conductor pattern.

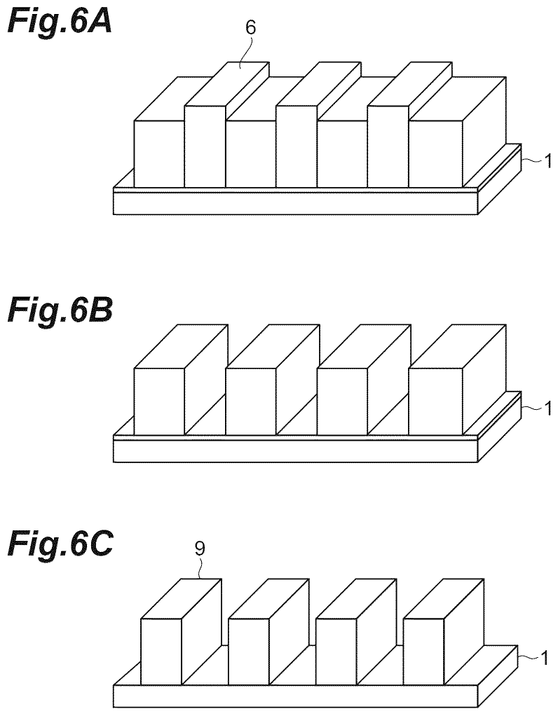

As illustrated in FIG. 6A, in the plating process, copper, solder, or the like is plated on the conductor layer 1b of the substrate 1 not covered with the resist using the resist pattern 6 formed on the substrate 1 including the conductor layer 1b as a mask. After the plating process, as shown in FIG. 6B, the resist is removed by removing the resist pattern 6, and as shown in FIG. 6C, the conductor layer 1b covered with the resist is subjected to etching to form the conductor pattern 9. The method of plating process may be electrolytic plating process or electroless plating process, and may be electrolytic plating process among them.

As described above, in the resist pattern inspection method according to the present embodiment, since the resist pattern 6 is subjected to an outer appearance inspection based on light emission from the substrate 1 on which the resist pattern 6 is formed, the defect 8 of the resist pattern 6 can be detected with a high accuracy in a short time as compared with the outer appearance inspection using the SEM.

In addition, in this resist pattern inspection method, the outer appearance inspection of the resist pattern 6 can be appropriately performed by using the contour 10 of the resist pattern 6 detected based on light emission from the substrate 1 on which the resist pattern 6 is formed as the outer appearance inspection of the resist pattern 6.

In the resist pattern inspection method, the defect 8 of the resist pattern 6 can be detected with high accuracy by comparing the detected contour 10 with the pattern data 11 for forming the resist pattern 6 as the outer appearance inspection of the resist pattern 6.

In addition, in this resist pattern inspection method, the formation state of the resist pattern 6 can be evaluated by measuring the line width of the resist pattern 6 based on the detected contour 10 as the outer appearance inspection of the resist pattern 6.

In addition, in this resist pattern inspection method, since the light emission intensity from the conductor surface of the substrate increases by adhering the light-emitting material onto the conductor surface of the substrate 1, the contrast between the light emission from the region 1c where the resist pattern 6 is not formed in the conductor surface of the substrate 1 and the light emission from the region 1d where the resist pattern 6 is formed in the conductor surface of the substrate 1 increases. Therefore, the detection accuracy of the contour 10 of the resist pattern 6 based on the light emission from the substrate 1 can be enhanced.

Meanwhile, light emission from the resist pattern 6 tends to be darker as the resist pattern 6 becomes thinner. Therefore, as the resist pattern 6 becomes thinner, the contrast between the light emission from the region 1c where the resist pattern 6 is not formed in the conductor surface of the substrate 1 and the light emission from the region 1d where the resist pattern 6 is formed in the conductor surface of the substrate 1 increases. Therefore, from the viewpoint of increasing the contrast between the light emission from the region 1c where the resist pattern 6 is not formed in the conductor surface of the substrate 1 and the light emission from the region 1d where the resist pattern 6 is formed in the conductor surface of the substrate 1, the thickness of the resist pattern 6 formed on the substrate 1 may be, for example, less than or equal to 500 μm, less than or equal to 300 μm, less than or equal to 100 μm, or less than or equal to 60 μm. Furthermore, the thickness of the resist pattern 6 formed on the substrate 1 may be, for example, greater than or equal to 0.05 μm, greater than or equal to 0.1 μm, greater than or equal to 1 μm, or greater than or equal to 5 μm. The minimum value and the maximum value of the thickness of the resist pattern 6 can be appropriately combined. For example, the thickness of the resist pattern 6 formed on the substrate 1 may be greater than or equal to 0.05 μm and less than or equal to 500 μm, greater than or equal to 0.1 μm and less than or equal to 300 μm, greater than or equal to 1 μm and less than or equal to 100 μm, or greater than or equal to 5 μm and less than or equal to 60 μm.

In this resist pattern inspection method, by forming the resist pattern 6 having a thickness of greater than or equal to 0.05 μm and less than or equal to 500 μm, greater than or equal to 0.1 μm and less than or equal to 300 μm, greater than or equal to 1 μm and less than or equal to 100 μm, or greater than or equal to 5 μm and less than or equal to 60 μm, it is possible to increase the contrast between the light emission from the region 1c where the resist pattern 6 is not formed in the conductor surface of the substrate 1 and the light emission from the region 1d where the resist pattern 6 is formed in the conductor surface of the substrate 1 while suppressing the resist pattern 6 from becoming too thick. Therefore, the detection accuracy of the contour 10 of the resist pattern 6 based on the light emission from the substrate 1 can be enhanced.

In the resist pattern manufacturing method according to the present embodiment, the contrast between the light emission from the region 1c where the resist pattern 6 is not formed in the conductor surface of the substrate 1 and the light emission from the region 1d where the resist pattern 6 is formed in the conductor surface of the substrate 1 increases by adhering the light-emitting material onto the conductor surface of the substrate 1. Therefore, for example, in a case where the contour 10 of the resist pattern 6 is detected based on light emission from the substrate 1 on which the resist pattern 6 is formed, the detection accuracy can be enhanced. In addition, in a case where the line width of the resist pattern 6 is measured or the like, it is easy to focus on the surface of the resist pattern 6 or the contour of the resist pattern 6.

In this resist pattern manufacturing method, by forming the resist pattern 6 having a thickness of greater than or equal to 0.05 μm and less than or equal to 500 μm, greater than or equal to 0.1 μm and less than or equal to 300 μm, greater than or equal to 1 μm and less than or equal to 100 μm, or greater than or equal to 5 μm and less than or equal to 60 μm, it is possible to increase the contrast between the light emission from the region 1c where the resist pattern 6 is not formed in the conductor surface of the substrate 1 and the light emission from the region 1d where the resist pattern 6 is formed in the conductor surface of the substrate 1 while suppressing the resist pattern 6 from becoming too thick. Therefore, for example, the detection accuracy of the contour 10 of the resist pattern 6 based on the light emission from the substrate 1 can be enhanced.

In the substrate selection method according to the present embodiment, since the resist pattern 6 is evaluated by the outer appearance inspection of the resist pattern 6 based on the light emission from the substrate 1, the substrate 1 can be selected with high accuracy in a short time as compared with the outer appearance inspection using the SEM.

In addition, in this substrate selection method, the substrate 1 can be appropriately evaluated by evaluating the substrate 1 according to the number or shape of defects of the resist pattern 6.

In addition, in this substrate selection method, since the light-emitting material is adhered on the conductor surface of the substrate 1 to be subjected to the outer appearance inspection in the outer appearance inspection step, the contrast between the light emission from the region 1c where the resist pattern 6 is not formed in the conductor surface of the substrate 1 and the light emission from the region 1d where the resist pattern is formed in the conductor surface of the substrate 1 increases. Therefore, the outer appearance inspection of the resist pattern 6 can be performed with high accuracy.

In the manufacturing method for a semiconductor package substrate or a printed circuit board according to the present embodiment, the conductor pattern 9 is formed by performing etching process or plating process on the substrate 1 in which the evaluation of the resist pattern 6 in the substrate selection method described above satisfies the references, so that the occurrence of failures such as disconnection or short circuit of the conductor pattern 9 can be suppressed.

The present invention is not limited to the above embodiment, and can be appropriately modified without departing from the gist of the present invention.

### EXAMPLES

Next, examples of the present disclosure will be described. However, the present disclosure is not limited to the following examples.

### 1. Photosensitive Element and Base Material

In first to fifth examples and a first comparative example, photosensitive elements and base materials shown in Table 1 and below were used. Note that the last two digits of the number of the Trade name of the photosensitive element indicate the film thickness (unit: μm) of the photosensitive layer.

### (Photosensitive Element)

F-1: Photosensitive element manufactured by increasing the amount of the photopolymerization initiator by 0.5 times and increasing the amount of the sensitizer by 0.3 times of ME-3606SG (Manufactured by Showa Denko Materials Co., Ltd., Trade name)
F-2: Photosensitive element manufactured by removing the MKG (malachite green) of RY-5115 (Manufactured by Showa Denko Materials Co., Ltd., Trade name), and increasing the amount of the photopolymerization initiator by 0.5 times and the amount of the sensitizer by 0.3 times
F-3: Photosensitive element manufactured by removing the MKG (malachite green) of RY-5125 (Manufactured by Showa Denko Material Co., Ltd., Trade name, photosensitive layer composition identical to (F-2)), and increasing the amount of the photopolymerization initiator by 0.5 times and the amount of the sensitizer by 0.3 times
F-4: FL-7225 (Manufactured by Showa Denko Materials Co., Ltd., Trade name)

### (Base Material)

S-1: Cu sputtered PET film (manufactured by GEOMATEC Co., Ltd., plate thickness: 125 μm, Ra<50 nm)
S-2: GL-102 (Manufactured by Ajinomoto Fine-Techno Co., Ltd., Trade name, Ra: about 100 nm)
S-3: MCL-E67 (manufactured by Showa Denko Materials Co., Ltd., Trade name, Ra: about 300 nm)

### 2. Preparation of Stacked Body

In the first, third and fourth examples, and the first comparative example, S-1 stored under moisture-proof conditions was used as a substrate having a copper layer as a conductive layer. In the second and fifth examples, a substrate having a copper layer as a conductive layer was washed with acid, washed with water, and dried with an air flow, and then the substrate was warmed to 80° C. Thereafter, the base materials S-1, S-2, and S-3 were immersed in a saturated aqueous solution of 1H-benzotriazole-5 carboxylic acid (FUJIFILM Wako Pure Chemical Corporation) at 23° C. for 60 minutes, washed with water, and dried with an air flow, and then further immersed in a saturated aqueous solution of rhodamine B (FUJIFILM Wako Pure Chemical Corporation) at 23° C. for 10 minutes to adhere a fluorescent dye to the copper surfaces of the base materials S-1, S-2, and S-3. After washing with water and drying with an air flow, the substrate was warmed to 80° C. Thereafter, in the first to fifth examples and the first comparative example, the photosensitive element was laminated (stacked) on the surface of the copper layer of the substrate. The lamination was performed at a pressure-bonding pressure of 0.4 MPa and a roll speed of 1.0 m/min using a heat roll of 110° C. so that the photosensitive layer of the photosensitive element was in contact with the surface of the copper layer of the substrate while peeling off the protective layer of the photosensitive element. In this way, a stacked body of the first to fifth examples and the first comparative example in which the substrate, the photosensitive layer, and the support were laminated in this order was obtained. The obtained stacked body was used as a test piece of the following test.

### 3. Preparation of Pattern Substrate

### First to Fourth Examples and First Comparative Example

Using a glass chromium-type photomask (for resolution evaluation or pattern inspection), the photosensitive layer was exposed at a predetermined energy amount using a projection exposure apparatus (Manufactured by USHIO INC., Trade name “UX-2240SM”) using an ultra-high pressure mercury lamp (365 nm) as a light source (exposure process). Note that a photomask having a wiring pattern with a line width/space width of x/x (x: 1 to 30, unit: μm) was used as the photomask for resolution evaluation, and a photomask having a wiring pattern with a line width/space width of x/x (x: 20, 30, 40, unit: μm) (pattern area: 90 mm×90 mm) was used as the photomask for pattern inspection.

After the exposure, the support was peeled off to expose the photosensitive layer, and a 1% by mass of sodium carbonate aqueous solution at 30° C. was sprayed for a time of twice the shortest development time (the shortest time for removing the unexposed portion) to remove the unexposed portion (development process). The substrate after development process exposed using the photomask for resolution evaluation is referred to as a pattern substrate for resolution evaluation, and the substrate after development process exposed using the photomask for pattern inspection is referred to as a pattern substrate for inspection. In the pattern substrate for resolution evaluation, the resolution was evaluated by the smallest line width/space width value among the resist patterns formed without causing wrinkles, meandering, and chipping of the line portion (exposed portion) while cleanly removing the space portion (unexposed portion). At this time, when the resist pattern was formed using the photomask for resolution evaluation in which the line width/space width of the wiring pattern was 30 μm/30 μm, the exposure amount at which the line width of the resist pattern was 30.0 μm was defined as the predetermined energy amount.

### Fifth Example

The photosensitive layer was exposed with a predetermined amount of energy using a direct drawing exposure device (Manufactured by Japan Orbotec Co., Ltd., Trade name “Nuvogo Fine 8”) using a semiconductor laser (375 nm and 405 nm mixed lines, ratio of the wavelengths can be arbitrarily changed (375 nm:405 nm=0:100 to 100:0)) as a light source. After the exposure, the development process was performed in the same procedure as in the first to fourth examples and the first comparative example to prepare a pattern substrate for resolution evaluation and a pattern substrate for inspection.

### 4. Outer Appearance Inspection of Resist Pattern

In the first to fifth examples, as an outer appearance inspection of a resist pattern, a defect of the resist pattern was detected by irradiating a pattern substrate for inspection with UV light to fluoresce the copper surfaces of the base materials S-1, S-2, and S-3 using AOI Orbotech Ultra Dimension 800 (Manufactured by Japan Orbotec Co., Ltd., Trade name). In the first comparative example, a defect of the resist pattern was observed using an SEM of SU-1500 (Manufactured by Hitachi High-Technologies Corporation, Trade name) as an outer appearance inspection of the resist pattern. At this time, the acceleration voltage was 15 kV, and the current value was 80 μA. With respect to the first to fifth examples and the first comparative example, the time for outer appearance inspection was evaluated, and with respect to the first to fifth examples, the pattern detection rate of defects in the resist pattern was also evaluated as an inspection accuracy. The pattern detection rate (inspection accuracy) refers to a probability that the inspection device can identify the contour of the resist pattern and recognize the pattern when performing the outer appearance inspection. That is, before the outer appearance inspection was performed, an appropriate gray level (threshold value for brightness binarization) was set according to each of the first to fifth examples by the inspection device, and when this setting was completed, it was OK, and when this setting was not completed and an error occurred, it was NG. Then, in the evaluation of the pattern detection rate of the defect of the resist pattern, a case where the pattern is OK every time is evaluated as A, a case where the pattern is not OK every time but the probability of NG is low is evaluated as B, and a case where the probability of NG is high is evaluated as C. In the evaluation of the time for the outer appearance inspection, it was rated A when less than 10 minutes/cm², it was rated B when greater than or equal to 10 minutes/cm² and less than 5000 minutes/100 cm², and it was rated C when greater than or equal to 5000 minutes/100 cm².

TABLE 1

| | | | | | | First |
|---|---|---|---|---|---|---|
| | First | Second | Third | Fourth | Fifth | comparative |
| Item | example | example | example | example | example | example |
| Photosensitive | F-1 | F-1 | F-2 | F-3 | F-4 | F-1 |
| element | | | | | | |
| Film thickness of | 6 | 6 | 15 | 25 | 25 | 6 |
| photosensitive | | | | | | |
| layer (μm) | | | | | | |
| Base material of | S-1 | S-2 | S-1 | S-1 | S-3 | S-1 |
| substrate | | | | | | |
| Surface roughness | <50 | 100 | <50 | <50 | 300 | <50 |
| of substrate Ra | | | | | | |
| (nm) | | | | | | |
| Inspection time | A | A | A | A | A | C |
| Inspection | A | A | A | A | A | — |
| accuracy | | | | | | |

### 5. Evaluation

As illustrated in table 1, in the first to fifth examples, the inspection time was significantly shortened as compared with the first comparative example. From this result, it was confirmed that a defect of the resist pattern can be detected in a shorter time by performing outer appearance inspection of the resist pattern based on fluorescence from the substrate on which the resist pattern is formed, as compared with the outer appearance inspection using the SEM.

In the first to fifth examples, the pattern detection rate was high. From this result, it was confirmed that, in the outer appearance inspection of the resist pattern performed based on the fluorescence from the substrate on which the resist pattern is formed, the contour of the resist pattern is easily detected and the inspection accuracy is high.

### REFERENCE SIGNS LIST

1 substrate
1a insulating layer
1b conductor layer
1c region of conductor surface of substrate where resist pattern is not formed
1d region of conductor surface of substrate where resist pattern is formed
2 photosensitive layer
2a photocured portion
2b uncured portion
3 support
4 stacked body
5 photomask
6 resist pattern
7 foreign matter
8 defect
9 conductor pattern
10 contour
11 pattern data

1. A resist pattern inspection method comprising
performing an outer appearance inspection of a resist pattern based on light emission from a substrate on which the resist pattern is formed.

2. The resist pattern inspection method according to claim 1, wherein
performing the outer appearance inspection includes detecting a contour of the resist pattern based on light emission from the substrate, and performing the outer appearance inspection of the resist pattern based on the detected contour.

3. The resist pattern inspection method according to claim 2, wherein
performing the outer appearance inspection includes comparing the detected contour with pattern data for forming the resist pattern.

4. The resist pattern inspection method according to claim 2, wherein
performing the outer appearance inspection includes measuring a line width of the resist pattern based on the detected contour.

5. The resist pattern inspection method according to claim 1, further comprising:
forming the resist pattern on the substrate; and
adhering a light-emitting material on a conductor surface of the substrate.

6. The resist pattern inspection method according to claim 5, wherein
the forming of the resist pattern includes forming the resist pattern having a thickness of greater than or equal to 0.05 μm and less than or equal to 500 μm.

7. A resist pattern manufacturing method comprising:
forming a resist pattern on a substrate; and
adhering a light-emitting material on a conductor surface of the substrate.

8. The resist pattern manufacturing method according to claim 7, wherein
the forming of the resist pattern includes forming the resist pattern having a thickness of greater than or equal to 0.05 μm and less than or equal to 500 μm.

9. A substrate selection method comprising:
performing an outer appearance inspection on a resist pattern based on light emission from a substrate on which the resist pattern is formed; and
evaluating the resist pattern based on the outer appearance inspection in performing the outer appearance inspection.

10. The substrate selection method according to claim 9, wherein
evaluating includes evaluating the resist pattern according to number of defects of the resist pattern.

11. The substrate selection method according to claim 9, wherein
a light-emitting material is adhered on a conductor surface of the substrate to be subjected to outer appearance inspection in performing the outer appearance inspection.

12. A manufacturing method for a semiconductor package substrate or a printed circuit board comprising:
forming a conductor pattern by performing etching process or plating process on a substrate in which the evaluation of the resist pattern in the substrate selection method according to claim 9 satisfies a reference.
